(19) United States
(12) Patent Application Publication
(10) Pub. No.: US 2024/0246811 A1
(43) Pub. Date: Jul. 25, 2024

(54) PRESSURE SENSOR STRUCTURE AND PRESSURE SENSOR DEVICE

(71) Applicant: Murata Manufacturing Co., Ltd., Nagaokakyo-shi (JP)

(72) Inventor: Ryosuke NIWA, Nagaokakyo-shi (JP)

(21) Appl. No.: 18/625,251

(22) Filed: Apr. 3, 2024

Related U.S. Application Data
(63) Continuation of application No. PCT/JP2022/037173, filed on Oct. 4, 2022.

(30) Foreign Application Priority Data
Oct. 5, 2021 (JP) 2021-164256

(51) Int. Cl. B81B 7/00; G01L 9/00

(52) U.S. Cl. CPC B81B 7/0029; G01L 9/0073; B81B 2201/0264; B81B 2203/0127; B81B 2203/04

(57) ABSTRACT

A pressure sensor structure includes a sensor body including a diaphragm plate defining and functioning as a sense electrode, a base electrode facing the diaphragm plate, and a sidewall layer maintaining a gap between the diaphragm plate and the base electrode, and a conductive base substrate supporting the sensor body. The sidewall layer includes a guard electrode layer and upper and lower guard electrode insulating layers electrically insulating the guard electrode layer. Surfaces of an outer side portion of each of the diaphragm plate and the sidewall layer are covered with an electrical insulating film that includes a contact region at which a portion of the guard electrode layer communicates with outside air.

### CROSS REFERENCE TO RELATED APPLICATIONS

This application claims the benefit of priority to Japanese Patent Application No. 2021-164256 filed on Oct. 5, 2021 and is a Continuation application of PCT Application No. PCT/JP2022/037173 filed on Oct. 4, 2022. The entire contents of each application are hereby incorporated herein by reference.

### BACKGROUND OF THE INVENTION

### 1. Field of the Invention

The present invention relates to pressure sensor structures to measure pressure such as atmospheric pressure and water pressure, and pressure sensor devices including pressure sensor structures.

### 2. Description of the Related Art

A pressure sensor can be manufactured by using MEMS (microelectromechanical system) technology, to which a semiconductor manufacturing technology is applied, and an ultra-compact sensor of approximately 0.5 mm to 2 mm square can be achieved, for example. A typical pressure sensor has a capacitor structure with two electrodes and can measure pressure by detecting a change in electrostatic capacitance caused by a change in ambient pressure.

FIG. 7 is a cross-sectional view showing an example of a conventional pressure sensor structure. The pressure sensor structure is disclosed in International Publication No. 2015/107453, for example, and includes a diaphragm plate 32 that functions as a sense electrode, a base electrode 31 that faces the diaphragm plate 32, a sidewall layer 20 and the like. The sidewall layer 20 includes a guard electrode layer 22 and electrical insulating layers 21 and 23 disposed above and below the guard electrode layer 22. A base substrate 10 is formed of a conductive material and conducted with the base electrode 31. The guard electrode layer 22 is formed in the same layer as the base electrode 31, and is sandwiched between the diaphragm plate 32 on the upper side thereof and the base substrate 10 on the lower side thereof to form a three-layer electrode structure. Thus, it becomes possible to cancel stray electrostatic capacitance unrelated to the pressure change.

The surface of the outer side portion of the upper portion, i.e., the diaphragm plate 32 and the sidewall layer 20, of the pressure sensor structure is completely covered with an electrical insulating film 40 that functions as a passivation film. The electrical insulating film 40, formed of an electrical insulating material such as SiNₓ, SiO₂ or the like, prevents a short circuit between the electrodes and protects the pressure sensor structure.

FIG. 8 is a circuit diagram showing an example of a capacitance conversion circuit that can be connected to the pressure sensor structure shown in FIG. 7. The capacitance conversion circuit includes an operational amplifier OP, a base terminal TB for the base electrode, a sense terminal TS for the sense electrode (the diaphragm plate), a guard terminal TG for the guard electrode, a voltage source CV, and a reference impedance RA. By using the capacitance conversion circuit described above, a voltage output indicating the electrostatic capacitance between the diaphragm plate and the base electrode can be obtained while canceling the stray electrostatic capacitance and suppressing the influence of disturbance.

### SUMMARY OF THE INVENTION

A pressure sensor structure according to an example embodiment of the present invention shown in FIGS. 5A and 5B is obtained by forming many of the pressure sensor structures on a single semiconductor wafer using MEMS technology and then cutting the formed pressure sensor structures into individual chips. The chip obtained is housed in a housing 50 made of a synthetic resin, together with an integrated circuit that performs signal processing, so that a pressure sensor device is completed.

In such a case, the lower portion of the pressure sensor structure, i.e., the rear surface and the side surface of the base substrate 10, is in close contact with the housing 50, while the upper portion of the pressure sensor structure is exposed to the outside air. Therefore, there is a possibility that a liquid LQ such as water may adhere to the electrical insulating film 40 due to condensation, flooding or the like. Since such liquid LQ generally includes conductive components such as ions, it can define and function as a conductor or an electrode. Therefore, the stray capacitance between the diaphragm plate 32 and the base substrate 10 may change, causing the pressure output value to shift. Further, the diaphragm plate 32 and the base electrode 31 may be affected by electromagnetic noises coming from outside, causing the pressure output value to shift.

Example embodiments of the present invention provide pressure sensor structures each able to reduce or prevent an influence of disturbance and to perform pressure measurement with high accuracy, and pressure sensor devices each including a pressure sensor structure according to an example embodiment of the present invention.

A pressure sensor structure according to an example embodiment of the present invention detects changes in electrostatic capacitance between electrodes, the pressure sensor structure including a sensor body including a diaphragm plate defining and functioning as a sense electrode, a base electrode facing the diaphragm plate, and a sidewall layer maintaining a gap between the diaphragm plate and the base electrode, and a conductive base substrate supporting the sensor body, wherein the sidewall layer includes a guard electrode layer and upper and lower guard electrode insulating layers electrically insulating the guard electrode layer, a surface of an outer side portion of the diaphragm plate and a surface of an outer side portion of the sidewall layer are covered with an electrical insulating film, and the electrical insulating film includes a contact region at which a portion of the guard electrode layer communicates with outside air.

A pressure sensor device according to an example embodiment of the present invention includes a pressure sensor structure according to an example embodiment of the present invention, a housing to house the pressure sensor structure, and a capacitance conversion circuit to process signals from the pressure sensor structure and to cancel stray electrostatic capacitance around the diaphragm plate.

According to example embodiments of the present invention, an influence of disturbance is able to be reduced or prevented and highly accurate pressure measurement is able to be performed.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a cross-sectional view showing an example of a pressure sensor structure according to Example Embodiment 1 of the present invention.

FIG. 2 is a circuit diagram showing an example of a capacitance conversion circuit that can be connected to the pressure sensor structure shown in FIG. 1.

FIG. 3 is a cross-sectional view showing an example of a pressure sensor structure according to Example Embodiment 2 of the present invention.

FIG. 4 is a cross-sectional view showing a state in which the pressure sensor structure shown in FIG. 3 is housed in a housing.

FIG. 5A is a cross-sectional view showing an example of a pressure sensor structure 1 according to Example Embodiment 4 of the present invention, and FIG. 5B is a plan view of the pressure sensor structure 1 shown in FIG. 5A in a state in which an electrical insulating film 40 is removed for ease of understanding.

FIG. 6 is a cross-sectional view showing a state in which the pressure sensor structure shown in FIG. 5 is housed in a housing.

FIG. 7 is a cross-sectional view showing an example of a conventional pressure sensor structure.

FIG. 8 is a circuit diagram showing an example of a capacitance conversion circuit that can be connected to the pressure sensor structure shown in FIG. 7.

### DETAILED DESCRIPTION OF THE EXAMPLE EMBODIMENTS

A pressure sensor structure according to an example embodiment of the present invention detects changes in electrostatic capacitance between electrodes, the pressure sensor structure including a sensor body including a diaphragm plate that defines and functions as a sense electrode, a base electrode that faces the diaphragm plate, and a sidewall layer that maintains a gap between the diaphragm plate and the base electrode, and a conductive base substrate that supports the sensor body, wherein the sidewall layer includes a guard electrode layer and upper and lower guard electrode insulating layers that electrically insulate the guard electrode layer, the surface of an outer side portion of the diaphragm plate and the surface of an outer side portion of the sidewall layer are covered with an electrical insulating film, and the electrical insulating film includes a contact region at which a portion of the guard electrode layer communicates with the outside air.

With such a configuration, even when a liquid such as water, for example, adheres to the electrical insulating film due to condensation, flooding or the like, for example, the guard electrode layer and the adhered liquid are maintained at the same or substantially the same potential via the contact region of the electrical insulating film. Thus, a shift of the pressure output value caused by liquid adhesion can be prevented, and the influence of the disturbance can be reduced or prevented.

The contact region may be provided so that a portion of the guard electrode layer communicates with the outside air through an opening provided in the diaphragm plate and the upper guard electrode insulating layer.

With such a configuration, by providing a contact region CT in a location where liquid tends to adhere and stagnate, the influence of the disturbance can be reduced or prevented to achieve highly accurate pressure measurement.

A conductive film electrically connected to the guard electrode layer via the contact region may be provided on the electrical insulating film.

With such a configuration, even when a liquid such as water, for example, adheres to the electrical insulating film due to condensation, flooding or the like, for example, the guard electrode layer and the adhered liquid are maintained at the same or substantially the same potential via the conductive film and the contact region of the electrical insulating film. Thus, the shift of the pressure output value caused by liquid adhesion can be prevented, and the influence of the disturbance can be reduced or prevented.

The conductive film may be made of, for example, Pt, Au, Ag, Al, Cu, Ir, Rh, Pd, Ti, Ni, Cr, Zr, Nb or Si, or an alloy including at least one of these elements.

With such a configuration, corrosion resistance of the conductive film is increased. Therefore, deterioration of the conductive film can be reduced or prevented even when the liquid adhering to the electrical insulating film is a corrosive liquid, such as chlorinated water or seawater, for example.

A pressure sensor device according to an example embodiment of present invention includes a pressure sensor structure according to an example embodiment of the present invention, a housing to house the pressure sensor structure, and a capacitance conversion circuit to process signals from the pressure sensor structure and to cancel stray electrostatic capacitance around the diaphragm plate.

With such a configuration, a pressure sensor device capable of reducing or preventing an influence of disturbances such as, for example, condensation, flooding, and electromagnetic noises can be achieved.

### Example Embodiment 1

FIG. 1 is a cross-sectional view showing an example of a pressure sensor structure 1 according to Example Embodiment 1 of the present invention. The pressure sensor structure 1 includes a sensor body and a base substrate 10 that supports the sensor body, in which the sensor body includes a diaphragm plate 32, a base electrode 31, and a sidewall layer 20.

The diaphragm plate 32 is made of a conductive material such as, for example, polycrystalline Si, amorphous Si, or single crystal Si, and defines and functions as a sense electrode that can deform in response to the ambient pressure difference. The diaphragm plate 32 shown in the present example is, for example, a single-layer configuration, but may include two or more layers.

The base electrode 31 is made of a conductive material such as, for example, polycrystalline Si, amorphous Si, or single crystal Si, and faces the diaphragm plate 32. The sidewall layer 20 is provided to maintain a gap G between the diaphragm plate 32 and the base electrode 31. The gap G is a space sealed from the outside, and is filled, for example, with an inert gas and maintained at a constant pressure.

The diaphragm plate 32 and the base electrode 31 define a parallel plate capacitor. The electrostatic capacitance C between the electrodes is expressed as C=ε×S/d, using the dielectric constant ε of the gap G, the electrode area S, and the interelectrode distance d. When the diaphragm plate 32 is elastically deformed in response to the pressure difference between the outside and the gap G, the interelectrode distance d changes, and the electrostatic capacitance C changes accordingly.

The sidewall layer 20 has a frame shape and surrounds the gap G, includes at least three layers, and includes a guard electrode layer 22, an electrical insulating layer 21 provided below the guard electrode layer 22 and the base electrode 31, and an electrical insulating layer 23 provided above the guard electrode layer 22. Here, the sidewall layer 20 shown in the present example is, for example, a three-layer configuration, but may include four or more layers. The guard electrode layer 22 shown in the present example is, for example, a single-layer configuration, but may include two or more layers. The electrical insulating layers 21 and 23 shown in the present example are each, for example, a single-layer configuration, but may each include two or more layers.

The base substrate 10 is made of a conductive material such as, for example, polycrystalline Si, amorphous Si, or single crystal Si. The base substrate 10 may include one or more layers, for example, an electrical insulating layer may be provided on the lower surface of the base substrate 10.

The planar shape of the diaphragm plate 32, the base electrode 31, and the sidewall layer 20 is, for example, rectangular or substantially rectangular, but may also be, for example, square or substantially square, circular or substantially circular, elliptical or substantially elliptical, polygonal, or the like.

The surface of the outer side portion of the diaphragm plate 32 and the surface of the outer side portion of the sidewall layer 20 are covered with an electrical insulating film 40 that defines and functions as a passivation film. The electrical insulating film 40, made of an electrical insulating material such as, for example, SiNₓ, SiO₂ or the like, prevents a short circuit between the electrodes and protects the pressure sensor structure.

In the present example embodiment, the electrical insulating film 40 does not cover the entire upper portion of the pressure sensor structure 1, and the electrical insulating film 40 includes a contact region CT at which a portion of the guard electrode layer 22 is exposed to the outside and communicates with the outside air. The contact region CT may be provided continuously along the perimeter of the guard electrode layer 22, or partially or intermittently, for example, as a dotted line, a dashed line, or a single-dotted line.

The function of the contact region CT is described below. A liquid such as, for example, water may adhere to the electrical insulating film 40 due to condensation, flooding or the like, for example. Since such a liquid generally includes ions and other conductive components, the stray capacitance between the diaphragm plate 32 and the base substrate 10 may change, causing the pressure output value to shift. In the present example embodiment, due to the presence of the contact region CT, even if the liquid adheres to the electrical insulating film 40, the guard electrode layer 22 and the adhered liquid are maintained at the same or substantially the same potential via the contact region CT. Thus, the shift of the pressure output value caused by liquid adhesion can be prevented, and the influence of the disturbance can be reduced or prevented.

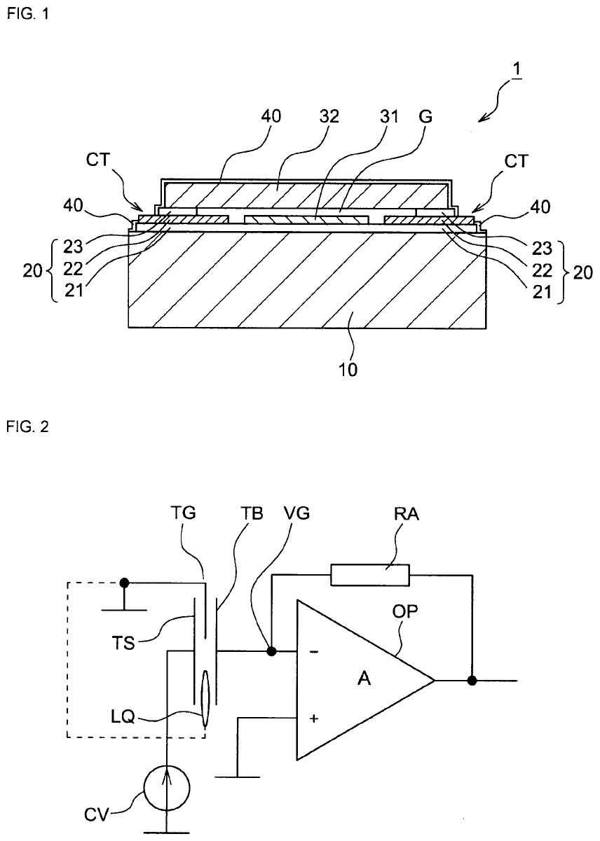

FIG. 2 is a circuit diagram showing an example of a capacitance conversion circuit that can be connected to the pressure sensor structure 1 shown in FIG. 1. The capacitance conversion circuit includes an operational amplifier OP, a base terminal TB for the base electrode, a sense terminal TS for the sense electrode (the diaphragm plate), a guard terminal TG for the guard electrode, a voltage source CV, and a reference impedance RA. If the liquid LQ adheres to the electrical insulating film 40, the electrostatic capacitance between the sense terminal TS and the base terminal TB is affected. However, since the guard electrode layer 22 and the adhered liquid are maintained at the same or substantially the same potential via the contact region CT, the shift of the pressure output value due to adhesion of the liquid LQ can be prevented.

In FIG. 2, the base terminal TB is connected to a virtual ground point VG of the inverting input of the operational amplifier OP, and the guard terminal TG is at ground potential. Therefore, the voltage and current between the guard electrode and the base electrode are negligible and have virtually no effect on the capacitance value measured between the base electrode and the diaphragm plate. The sense terminal TS is connected to the voltage source CV such that the current between the guard electrode and the diaphragm plate is negligible and the capacitance value measured between the diaphragm plate and the base electrode is not substantially affected. The electrostatic capacitance between the guard electrode and the base electrode is connected between the ground and the virtual ground point VG and does not substantially affect the capacitance value measured between the diaphragm plate and the base electrode.

The electrostatic capacitance between the base terminal TB and the sense terminal TS is CS, and the electrostatic capacitance between the base terminal TB and the guard terminal TG is CL. Assume that the voltage source CV is an AC voltage source with an effective voltage Ui, the feedback circuit element RA is a capacitor with electrostatic capacitance equal to CF, and the open loop gain of the amplifier OP is A. The output voltage Uo of the amplifier is expressed as below.

$$\begin{matrix}Formula 1 & \\ {U}_{O} = \frac{{C}_{S}}{{C}_{L} / A + {C}_{F}} {U}_{i} & ( 1 )\end{matrix}$$

Thus, the influence of CL decreases with the amount of the open loop gain A of the amplifier. The electrostatic capacitance between the sense terminal TS and the guard terminal TG is also connected in parallel with a voltage source Ui which, as an ideal voltage source, can supply current to the electrostatic capacitance without changing the voltage, thus not substantially affecting the output voltage.

### Example Embodiment 2

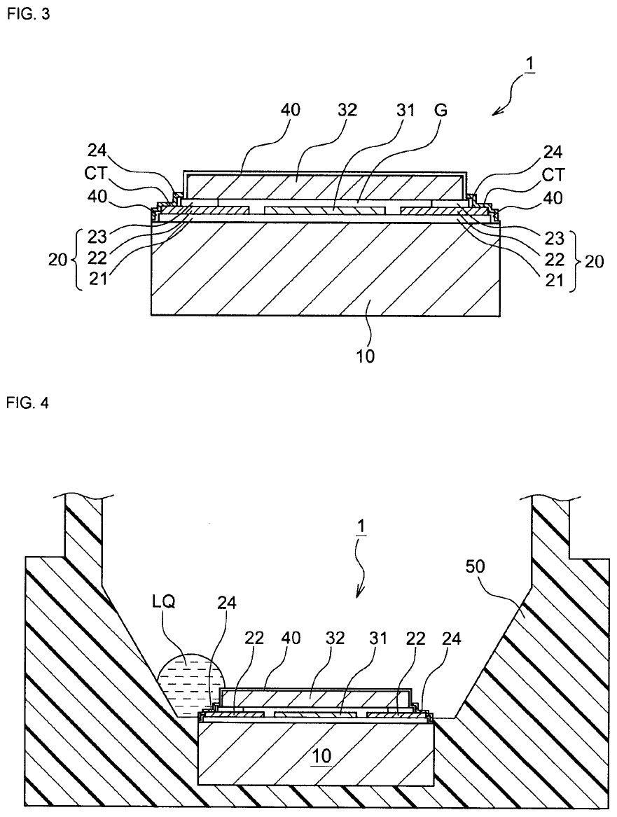

FIG. 3 is a cross-sectional view showing an example of a pressure sensor structure 1 according to Example Embodiment 2 of the present invention. The pressure sensor structure 1 includes a sensor body and a base substrate 10 that supports the sensor body, in which the sensor body includes a diaphragm plate 32, a base electrode 31, and a sidewall layer 20. Since the materials and functions of these components are the same or substantially the same as those in the structure shown in FIG. 1, the explanations of these components will not be repeated.

In the present example embodiment, a conductive film 24 electrically connected to the guard electrode layer 22 via the contact region CT is provided on the electrical insulating film 40. The conductive film 24 covers the outer wall of the sidewall layer 20 while in physical contact with the contact region CT. This increases the probability of conduction between the liquid LQ and the guard electrode layer 22. The conductive film 24 described above may be provided continuously along the perimeter of the guard electrode layer 22, or it may be provided, for example, partially or intermittently, or in a mesh-like fashion.

FIG. 4 is a cross-sectional view showing a state in which the pressure sensor structure 1 shown in FIG. 3 is housed in a housing 50. The lower portion of the pressure sensor structure 1, i.e., the rear surface and the side surface of the base substrate 10, is in close contact with the housing 50, while the upper portion of the pressure sensor structure is exposed to the outside air. Therefore, there is a possibility that a liquid LQ such as, for example, water may adhere to an electrical insulating film 40 due to condensation, flooding or the like, for example. Since the inner space of the housing 50 is recessed to have a bowl vessel shape, the liquid LQ tends to stagnate near the outer wall of the sidewall layer 20. The liquid LQ comes into physical contact with the conductive film 24, and the guard electrode layer 22 and the adhered liquid LQ are maintained at the same or substantially the same potential via the conductive film 24 and the contact region CT of the electrical insulating film 40. Thus, the shift of the pressure output value caused by liquid adhesion can be prevented, and the influence of the disturbance can be reduced or prevented.

The conductive film 24 may be made of, for example, Pt, Au, Ag, Al, Cu, Ir, Rh, Pd, Ti, Ni, Cr, Zr, Nb or Si, or an alloy including at least one of these elements, such as, for example, a stainless steel, an aluminum alloy, a titanium alloy, or a nickel alloy. Thus, the corrosion resistance of the conductive film 24 is increased. Therefore, deterioration of the conductive film 24 can be reduced or prevented even when the liquid adhering to the electrical insulating film 40 is a corrosive liquid, such as chlorinated water or seawater, for example. Examples of methods for forming the conductive film 24 include evaporation, sputtering, plating, and coating.

### Example Embodiment 3

According to Example Embodiment 3 of the present invention, the pressure sensor structure 1 shown in FIGS. 1 and 3, together with the capacitance conversion circuit shown in FIG. 2, is housed in the housing 50 as shown in FIG. 4. Thus, a pressure sensor device capable of reducing or preventing the influence of a disturbance such as, for example, condensation, flooding, and electromagnetic noises can be achieved.

### Example Embodiment 4

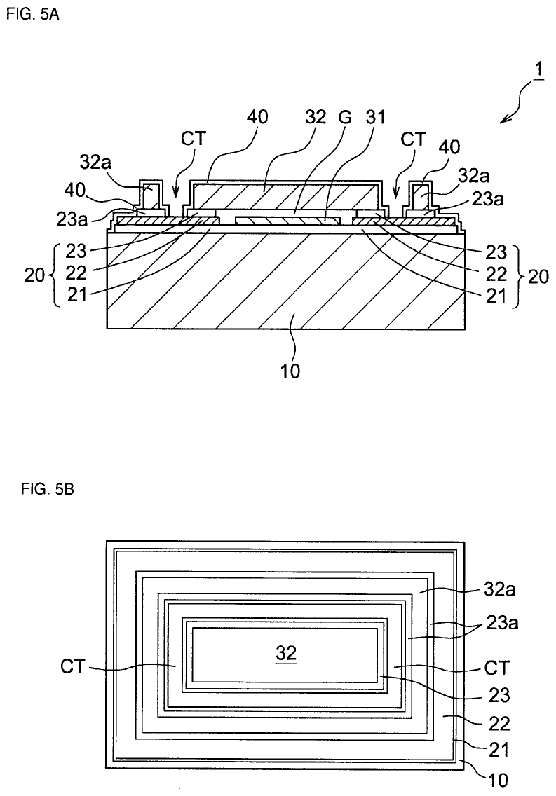

FIG. 5A is a cross-sectional view showing an example of a pressure sensor structure 1 according to Example Embodiment 4 of the present invention. FIG. 5B is a plan view of the pressure sensor structure 1 shown in FIG. 5A in a state in which an electrical insulating film 40 is removed for ease of understanding. The pressure sensor structure 1 includes a sensor body and a base substrate 10 that supports the sensor body, in which the sensor body includes a diaphragm plate 32, a base electrode 31, and a sidewall layer 20. Since the materials and functions of these components are the same or substantially the same as those in the structure shown in FIG. 1, the explanations of these components will not be repeated.

In the present example embodiment, in the pressure sensor structure shown in FIG. 1, the electrical insulating layer 23, the diaphragm plate 32, and the electrical insulating film 40 are partially removed to provide an opening through which a portion of the upper surface of the guard electrode layer 22 is exposed to the outside air. The exposed portion of the guard electrode layer 22 defines and functions as a contact region CT that communicates with the outside air. FIG. 5B illustrates a case where the contact region CT is a rectangular or substantially rectangular continuous line. In addition to rectangular or substantially rectangular shape, the contact region CT may be other geometric shapes such as, for example, square or substantially square, circular or substantially circular, elliptical or substantially elliptical, or the like, and may be partially or intermittently provided such as a dotted line, a dashed line, or single-pointed line in addition to the continuous line. An electrical insulating layer 23a and a diaphragm plate 32a remain in the outer side portion of the contact region CT. In such a manner, by providing the contact region CT in a location where liquid tends to adhere and stagnate, the influence of disturbance can be reduced or prevented to achieve highly accurate pressure measurement.

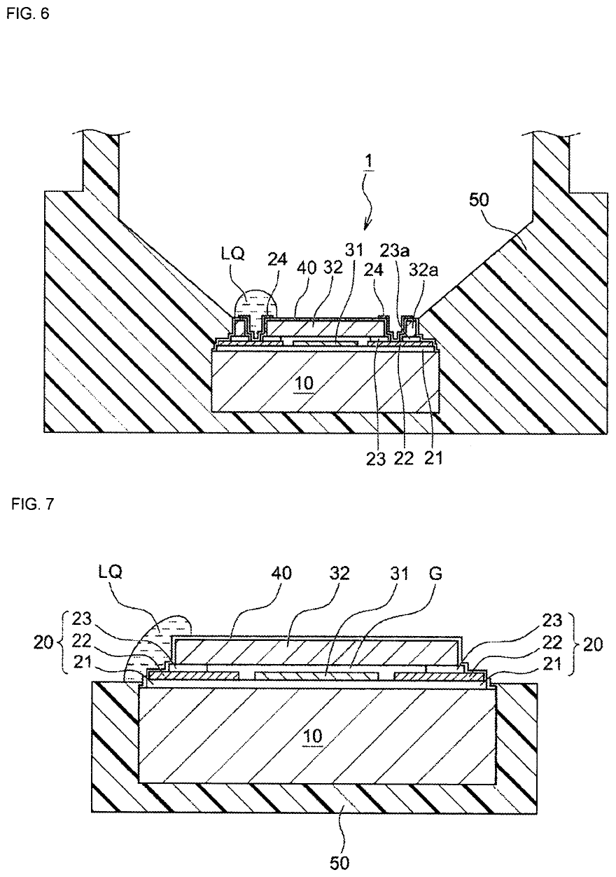

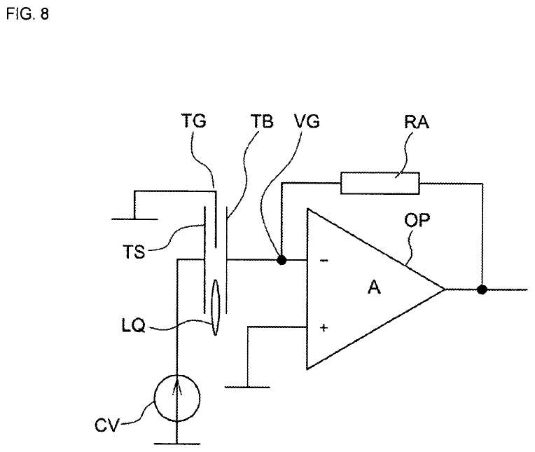

FIG. 6 is a cross-sectional view showing a state in which the pressure sensor structure 1 shown in FIGS. 5A and 5B are housed in a housing 50. As in Example Embodiment 2, the pressure sensor structure 1 includes a conductive film 24 electrically connected to the guard electrode layer 22 via the contact region CT on the electrical insulating film 40. The conductive film 24 may be omitted as in Example Embodiment 1.

The lower portion of the pressure sensor structure 1, i.e., the rear surface and the side surface of the base substrate 10, is in close contact with the housing 50, while the upper portion of the pressure sensor structure is exposed to the outside air. Therefore, there is a possibility that a liquid LQ such as, for example, water may adhere to the electrical insulating film 40 due to condensation, flooding or the like, for example. Since the inner space of the housing 50 is recessed to have a bowl vessel shape, the liquid LQ tends to stagnate near the outer wall of the sidewall layer 20. The liquid LQ comes into physical contact with the conductive film 24, and the guard electrode layer 22 and the adhered liquid LQ are maintained at the same or substantially the same potential via the conductive film 24 and the contact region CT of the electrical insulating film 40. Thus, the shift of the pressure output value caused by liquid adhesion can be prevented, and the influence of the disturbance can be reduced or prevented.

The conductive film 24 may be made of, for example, Pt, Au, Ag, Al, Cu, Ir, Rh, Pd, Ti, Ni, Cr, Zr, Nb or Si, or an alloy including at least one of these elements, such as, for example, a stainless steel, an aluminum alloy, a titanium alloy, or a nickel alloy. Thus, the corrosion resistance of the conductive film 24 is increased. Therefore, deterioration of the conductive film 24 can be reduced or prevented even when the liquid adhering to the electrical insulating film 40 is a corrosive liquid, such as chlorinated water or seawater, for example. Examples of methods for forming the conductive film 24 include evaporation, sputtering, plating, and coating.

### Example Embodiment 5

According to Example Embodiment 5 of the present invention, the pressure sensor structure 1 shown in FIGS. 5A and 5B, together with the capacitance conversion circuit shown in FIG. 2, is housed in the housing 50 as shown in FIG. 6. Thus, a pressure sensor device capable of reducing or preventing the influence of the disturbance such as, for example, condensation, flooding, and electromagnetic noises can be achieved.

Although the present invention has been fully described in connection with example embodiments with reference to the accompanying drawings, various variations and modifications apparent to those skilled in the art may be made. Such variations and modifications are to be understood as included within the scope of the present invention as defined by the appended claims unless they depart therefrom.

Example embodiments of the present invention are extremely useful in industry since they can reduce or prevent the influence of the disturbance and obtain pressure sensor structures capable of performing highly accurate pressure measurement.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A pressure sensor structure to detect changes in electrostatic capacitance between electrodes, the pressure sensor structure comprising:
a sensor body including a diaphragm plate defining and functioning as a sense electrode, a base electrode facing the diaphragm plate, and a sidewall layer maintaining a gap between the diaphragm plate and the base electrode; and
a conductive base substrate supporting the sensor body; wherein
the sidewall layer includes a guard electrode layer and upper and lower guard electrode insulating layers electrically insulating the guard electrode layer;
a surface of an outer side portion of the diaphragm plate and a surface of an outer side portion of the sidewall layer are covered with an electrical insulating film; and
the electrical insulating film includes a contact region at which a portion of the guard electrode layer communicates with outside air.

2. The pressure sensor structure according to claim 1, wherein the contact region is provided so that a portion of the guard electrode layer communicates with the outside air through an opening in the diaphragm plate and the upper guard electrode insulating layer.

3. The pressure sensor structure according to claim 1, wherein a conductive film electrically connected to the guard electrode layer via the contact region is provided on the electrical insulating film.

4. The pressure sensor structure according to claim 3, wherein the conductive film is made of Pt, Au, Ag, Al, Cu, Ir, Rh, Pd, Ti, Ni, Cr, Zr, Nb or Si, or an alloy including at least one of Pt, Au, Ag, Al, Cu, Ir, Rh, Pd, Ti, Ni, Cr, Zr, Nb or Si.

5. The pressure sensor structure according to claim 1, wherein the diaphragm plate is made of polycrystalline Si, amorphous Si, or single crystal Si.

6. The pressure sensor structure according to claim 1, wherein the base electrode is made of polycrystalline Si, amorphous Si, or single crystal Si.

7. The pressure sensor structure according to claim 1, wherein an inert gas is located in the gap.

8. The pressure sensor structure according to claim 1, wherein the sidewall layer has a frame shape surrounding the gap.

9. The pressure sensor structure according to claim 1, wherein a planar shape of the diaphragm plate, the base electrode, and the sidewall is rectangular or substantially rectangular.

10. The pressure sensor structure according to claim 1, wherein the electrical insulating film is made of SiNₓ or SiO₂.

11. A pressure sensor device comprising:
the pressure sensor structure according to claim 1;
a housing to house the pressure sensor structure; and
a capacitance conversion circuit to process signals from the pressure sensor structure and to cancel stray electrostatic capacitance around the diaphragm plate.

12. The pressure sensor device according to claim 11, wherein the contact region is provided so that a portion of the guard electrode layer communicates with the outside air through an opening in the diaphragm plate and the upper guard electrode insulating layer.

13. The pressure sensor device according to claim 11, wherein a conductive film electrically connected to the guard electrode layer via the contact region is provided on the electrical insulating film.

14. The pressure sensor device according to claim 13, wherein the conductive film is made of Pt, Au, Ag, Al, Cu, Ir, Rh, Pd, Ti, Ni, Cr, Zr, Nb or Si, or an alloy including at least one of Pt, Au, Ag, Al, Cu, Ir, Rh, Pd, Ti, Ni, Cr, Zr, Nb or Si.

15. The pressure sensor device according to claim 11, wherein the diaphragm plate is made of polycrystalline Si, amorphous Si, or single crystal Si.

16. The pressure sensor device according to claim 11, wherein the base electrode is made of polycrystalline Si, amorphous Si, or single crystal Si.

17. The pressure sensor device according to claim 11, wherein an inert gas is located in the gap.

18. The pressure sensor device according to claim 11, wherein the sidewall layer has a frame shape surrounding the gap.

19. The pressure sensor device according to claim 11, wherein a planar shape of the diaphragm plate, the base electrode, and the sidewall is rectangular or substantially rectangular.

20. The pressure sensor structure according to claim 11, wherein the electrical insulating film is made of SiNₓ or SiO₂.
